(19) United States
(12) Patent Application Publication
(10) Pub. No.: US 2026/0032956 A1
(43) Pub. Date: Jan. 29, 2026

(54) MODIFYING GATE ALL AROUND FINFET FINS FROM BACKSIDE

(71) Applicant: International Business Machines Corporation, Armonk, NY (US)

(72) Inventors: Tsung-Sheng Kang, Ballston Lake, NY (US); Gopal Sankar Kenath, Troy, NY (US); Tao Li, Slingerlands, NY (US); Ruilong Xie, Niskayuna, NY (US)

(21) Appl. No.: 18/780,678

(22) Filed: Jul. 23, 2024

(51) Int. Cl. H01L 29/423; H01L 21/8238; H01L 27/092; H01L 29/06; H01L 29/66; H01L 29/775; H01L 29/78; H01L 29/786

(52) U.S. Cl. CPC H10D 30/6735; H10D 30/014; H10D 30/43; H10D 30/6211; H10D 30/6757; H10D 62/121; H10D 84/0167; H10D 84/0193; H10D 84/038; H10D 84/853

(57) ABSTRACT

A semiconductor IC device is presented and includes a first region and a second region. The first region includes a first channel above a backside interlayer dielectric (ILD). The first channel includes a vertically orientated top channel segment stacked over a vertically orientated bottom channel segment and has a first effective channel width. The second region includes a second channel above the backside ILD. The second channel has a second effective channel width that is less than the first effective channel width. The reduced second effective channel width may be provided by removing an associated vertically orientated bottom channel segment of the second channel from the backside of the semiconductor IC device.

### BACKGROUND

Semiconductor integrated circuit (IC) devices have become ubiquitous within many products, particularly as they continue to decrease in cost and size. There is a continued desire to reduce the size of structural features and/or to provide a greater number of structural features for a given device size. Miniaturization, in general, allows for increased performance at lower power levels and lower cost. Present technology is at or approaching atomic level scaling of certain micro-devices such as transistors, or the like.

To achieve expected transistor functionality, the gate electric field should typically control the channel and the drain electric field should have a lesser effect on the channel. Otherwise, the transistor will show a set of unwanted effects called short channel effects. One way to reduce the propensity of short channel effects is to increase the effective gate width, which is a dimension of the periphery of the gate that is in contact with the channel. For clarity, the effective gate width may also be referred herein as the effective channel width. However, in some applications, a relatively large effective channel width may not be desirable.

### SUMMARY

The present disclosure relates to fabrication methods and resulting structures for semiconductor integrated circuit (IC) devices. More specifically, the present disclosure relates to fabrication methods and resulting semiconductor IC devices that include a FinFET that have channels that can have relatively different or variable effective channel widths and/or different effective channel widths.

In an embodiment of the disclosure, a semiconductor IC device is presented. The semiconductor IC device includes a first region and a second region. The first region includes a first channel above a backside ILD. The first channel includes a top channel segment that has a vertical orientation and is stacked over a bottom channel segment that also has a vertical orientation. The first channel has a first effective channel width. The second region includes a second channel that has a vertical orientation and is above the backside ILD. The second channel has a second effective channel width that is less than the first effective channel width.

In an embodiment of the disclosure, a semiconductor IC device is presented. The semiconductor IC device includes a first transistor and a second transistor. The first transistor includes a pair of segmented channels above a backside ILD. The pair of segmented channels has a first effective channel width. Each segmented channel of the pair of segmented channels includes a top channel segment that has a vertical orientation stacked over a bottom channel segment that also has a vertical orientation. The second transistor includes a pair of second channels above the backside ILD. The pair of second channels has a second effective channel width that is less than the first effective channel width.

In another embodiment of the disclosure, a semiconductor IC device fabrication method is presented. The method includes forming a first segmented channel and a second segmented channel within a substrate structure. The first segmented channel and the second segmented channel both includes a top channel segment that has a vertical orientation stacked over a bottom channel segment that also has a vertical orientation. The method further includes, from a backside of the semiconductor IC device, removing the bottom channel segment of the second segmented channel and maintaining the bottom channel segment of the first segmented channel.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts cross-sectional views a semiconductor IC device that includes transistors that have channel(s) that can have relatively different or variable channel widths, according to embodiments of the disclosure.

FIG. 2 depicts a partial top-down view of a semiconductor IC device that includes transistors that have channel(s) that can have relatively different or variable channel widths, according to embodiments of the disclosure.

FIG. 3 through FIG. 14 depict respective fabrication cross-sectional views of a semiconductor IC device that includes transistors that have channel(s) that can have relatively different or variable channel widths, according to embodiments of the disclosure.

FIG. 15 depicts a method of fabricating a semiconductor IC device that includes FinFET that have channel(s) that can have relatively different or variable channel widths. according to embodiments of the disclosure.

### DETAILED DESCRIPTION

Aspects of the disclosure may limit short channel effects within transistors and may allow for further scaling of transistors. For example, aspects of the disclosure, teach a semiconductor IC device that includes a first region and a different second region. The first region includes a first segmented channel above a backside interlayer dielectric (ILD). The first segmented channel has a first effective channel width and includes a first vertically orientated top channel segment stacked over a first vertically orientated bottom channel segment. The second region includes a second channel above the backside ILD. The second channel has a second effective channel width that is less than the first effective channel width. Therefore, the semiconductor IC device provides flexibility in achieving variable or different effective channel widths in different areas or regions of the semiconductor IC device, which may increase semiconductor IC device fabrication efficiency, yield, and/or performance.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions.

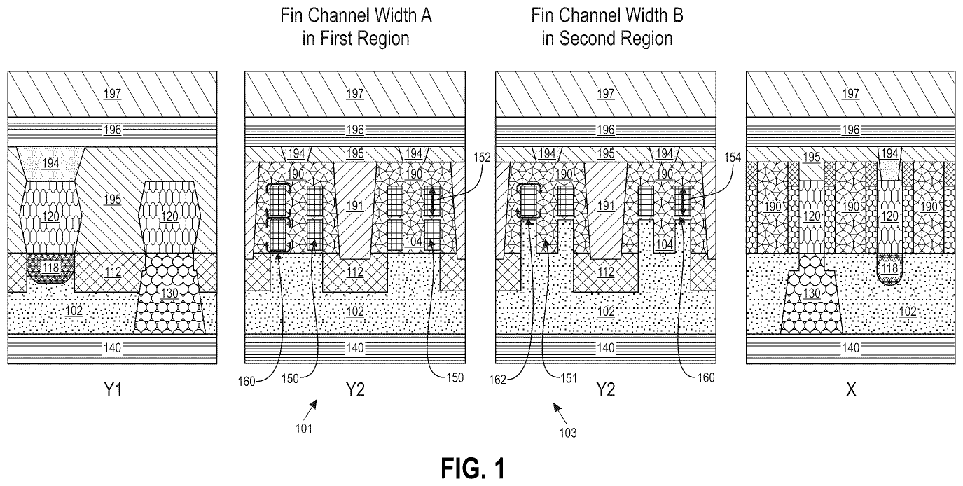

Referring now to the drawings in which like numerals represent the same or similar elements and initially to FIG. 1 which depicts cross-sectional views a semiconductor IC device 100. The semiconductor device 100 may include backside interlayer dielectric (ILD) 102, one or more STI regions 112, one or more source/drain regions 120, one or more backside contact placeholders 118, one or more gate structures 190, one or more gate inner spacers 260, one or more gate cut regions 191, one or more frontside ILD instances 195, one or more frontside contacts 344, a frontside back end of line (BEOL) network 196, carrier wafer 197, one or more backside contacts 130, and/or a backside BEOL network 140.

One or more transistors within the semiconductor IC device 100 may utilize the above recited structures. For example, a first transistor may include a pair of segmented channels(s) 150 that are connected to associated source/drain regions 120 and to an associated gate structure 190. Respective gate inner spacers 180 may adequately electrically isolate the gate structure 190 from the respective source/drain regions 120. A respective frontside contact 194 may electrically connect an underlying region to the frontside BEOL network 196 and a respective backside contact 130 may electrically connect an above region to the backside BEOL network 140, etc. A different transistor may include a pair of channels(s) 151 that are connected to associated source/drain regions 120 and to and associated gate structure 190. In this example, the pair of segmented channel(s) 150 have a relatively larger effective channel width A (e.g., summation of a perimeter 160 of each channel segment associated with the same S/D region(s) 120, as depicted) than the pair of channels 151 that have a relatively smaller effective channel width B (e.g., summation of a perimeter 162 of each channel segment associated with the same S/D region(s) 120, as depicted). The perimeter 160 may be twice a vertical height 152 plus twice a horizontal thickness of the applicable channel segment. Similarly, the perimeter 162 may be twice a vertical height 154 plus twice a horizontal thickness of the applicable channel segment.

In a particular embodiment of the present disclosure, an instance of semiconductor IC device 100 is presented. The semiconductor IC device 100 includes a first region 101 and a second region 103. The first region 101 includes a first channel (e.g., the pair of segmented channels 150, or the like) above the backside ILD 102. The first channel includes a vertically orientated top channel segment stacked over a vertically orientated bottom channel segment and has a first effective channel width (e.g., effective channel width A). The second region 103 includes a second channel (e.g., the pair of channels 151, or the like) above the backside ILD 102. The second channel has a second effective channel width (e.g., effective channel width B). that is less than the first effective channel width.

The semiconductor IC device 100 provides flexibility in achieving variable or different effective channel widths in different areas or regions 101, 103 of the semiconductor IC device 100, which may increase semiconductor IC device 100 fabrication efficiency, yield, and/or performance. For example, the effective channel widths A, B may enable flexibility of semiconductor IC device 100 macro designs or applications, such as SRAM, or the like.

In an example, a top surface of the vertically orientated top channel segment is coplanar with a top surface of the second channel. The coplanarity of the top surfaces of the channels in the different regions 101, 103 may result from the processing of the channels from the backside of semiconductor IC device 100.

In an example, the first region 101 further includes a first transistor that has first source/drain (S/D) regions 120 and the first channel. The respective end surfaces of the vertically orientated top channel segment and the vertically orientated bottom channel segment are in direct contact with the first S/D regions 120. In other words, the first transistor may be at least partially formed to include the first source/drain regions 120 which may be directly connected to respective end surfaces of the first channel.

In an example, the second region 103 further comprises a second transistor comprising second S/D regions 120 and the second channel. The respective end surfaces of the second channel are in direct contact with the second S/D regions 120. In other words, the second transistor may be at least partially formed to include the second source/drain regions 120 which may be directly connected to respective end surfaces of the second channel.

In an example, a bottom surface of the vertically orientated bottom channel segment is above a top surface of first shallow trench isolation (STI) regions 112 that at least partially bound the first transistor. This may result due from the segmented fabrication of the first channel and/or a sacrificial layer that existed prior to the fabrication of the first channel between the first channel and an underlying substrate structure.

In an example, a bottom surface of the second channel is above the bottom surface of the vertically orientated bottom channel segment. This may result from the removal of an a vertically orientated bottom channel segment that was once associated with the second channel.

In an example, the first region 101 further comprises a first gate structure 190 that wraps around a perimeter 160 of the vertically orientated top channel segment and a perimeter 160 of the vertically orientated bottom channel segment. In other words, the first channel may be a gate all around (GAA) channel which may provide for efficient electrostatic control of the first channel by the first gate structure 190.

In an example, the second region 103 further comprises a second gate structure 190 that wraps around a perimeter of the second channel. In other words, the second channel may be a gate all around (GAA) channel which may provide for efficient electrostatic control of the second channel by the second gate structure 190.

In an example, a bottom surface of the second gate structure 190 is substantially coplanar with a bottom surface of the first gate structure 190. For example, the gate structures 190 may be formed upon the same underlying surface.

In an example, the backside ILD 102 comprises a backside ILD portion 104 between a bottom surface of the second channel and the top surface of the second STI regions 112. This may result due to the removal of the vertically orientated bottom channel segment that was once associated with the second channel prior to the formation of the backside ILD portion 104.

In an example, the semiconductor IC device further includes the frontside BEOL network 196 and the backside BEOL network 140. The backside BEOL network 140 may further allow for the full or partial decoupling of signal routing and/or power routing and/or allows for dividing or splitting power wires and/or signal wires between both the frontside and backside of the semiconductor IC device 100. By incorporating the backside BEOL network 140, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

In an example, the first gate structure 190 and the second gate structure 190 are respectively electrically connected to the frontside BEOL network 196. For example, the gate structures 190 may be electrically connected to the frontside BEOL network 196 by respective one or more frontside contacts 194, for example, to take advantage of the full or partial decoupling of signal routing and/or power routing between the frontside BEOL network 196 and the backside BEOL network 140.

In an example, one of the first S/D regions 120 is electrically connected to the frontside BEOL network 196 by a frontside contact 194 and another of the first S/D regions 120 is electrically connected to the backside BEOL network 140 by a backside contact 130 to take advantage of the full or partial decoupling of signal routing and/or power routing between the frontside BEOL network 196 and the backside BEOL network 140.

In an example, the first transistor further includes a first gate inner spacer 180 in contact with a sidewall of the first gate structure 190 and with a sidewall of one of the first S/D regions 120 and a second gate inner spacer 180 in contact with an opposite sidewall of the first gate structure 190 and with a sidewall of another of the first S/D regions 120. The gate inner spacers 180 may adequately electrically isolate the gate structure 190 from the respective S/D regions 120.

In a particular embodiment of the present disclosure, another instance of semiconductor IC device 100 is presented. The semiconductor IC device 100 includes a first transistor comprising a pair of segmented channels 150 above a backside ILD 102. The pair of segmented channels 150 have the first effective channel width A. The semiconductor IC device 100 further includes a second transistor comprising a pair of second channels 151 above the backside ILD 102. The pair of second channels 151 have the second effective channel width B that is less than the first effective channel width A.

The semiconductor IC device 100 provides flexibility in achieving variable or different effective channel widths in different areas or regions 101, 103 of the semiconductor IC device 100, which may increase semiconductor IC device 100 fabrication efficiency, yield, and/or performance. For example, the effective channel widths A, B may enable flexibility of semiconductor IC device 100 macro designs or applications, such as SRAM, or the like.

In an example, each segmented channel of the pair of segmented channels 150 includes a vertically orientated top channel segment stacked over a vertically orientated bottom channel segment. In other words, each of the channel segments have a vertical height (e.g., height 152) that is greater than a horizontal thickness (e.g., thickness 164). For example, the vertically orientated channel segments may be vertical oriented fins, vertical oriented nanosheets, etc.

In an example, the first transistor further includes first S/D regions 120 and respective end surfaces of the vertically orientated top channel segments and the vertically orientated bottom channel segments are in direct contact with the first S/D regions 120. In other words, the first transistor may be at least partially formed to include the first source/drain regions 120 which may be directly connected to respective end surfaces of the first channel.

In an example, the first transistor further includes the first gate structure 190 that wraps around a respective perimeter of the vertically orientated top channel segments and a respective perimeter of the vertically orientated bottom channel segments. In other words, the first channel may be a GAA channel which may provide for efficient electrostatic control of the first channel by the first gate structure 190.

In an example, respective top surfaces of the vertically orientated top channel segments are substantially coplanar with respective top surfaces of the pair of second channels. The coplanarity of the top surfaces of the channels in the different regions 101, 103 may result from the processing of the channels from the backside of semiconductor IC device 100.

In a particular embodiment of the present disclosure, a semiconductor IC device fabrication method is present. The method includes forming a first segmented channel 150 and a second segmented channel 150 within a substrate structure. The first segmented channel 150 and the second segmented channel 150 both comprise a vertically orientated top channel segment stacked over a vertically orientated bottom channel segment. The method further includes, from a backside of the semiconductor IC device, removing the vertically orientated bottom channel segment of the second segmented channel 150 (e.g., resultantly forming second channel 151) and maintaining the vertically orientated bottom channel segment of the first segmented channel 150.

The semiconductor IC device 100 fabrication method provides flexibility in achieving variable or different effective channel widths in different areas or regions 101, 103 of the semiconductor IC device 100, which may increase semiconductor IC device 100 fabrication efficiency, yield, and/or performance. For example, the effective channel widths A, B may enable flexibility of semiconductor IC device 100 macro designs or applications, such as SRAM, or the like.

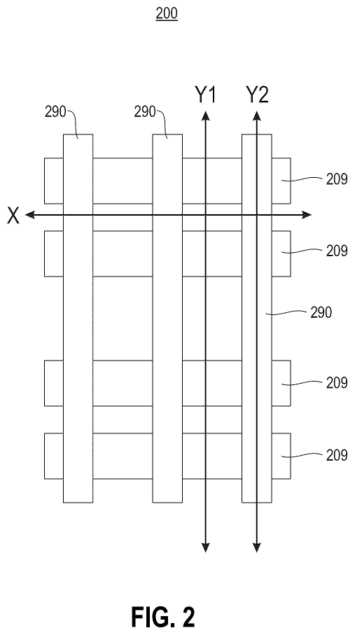

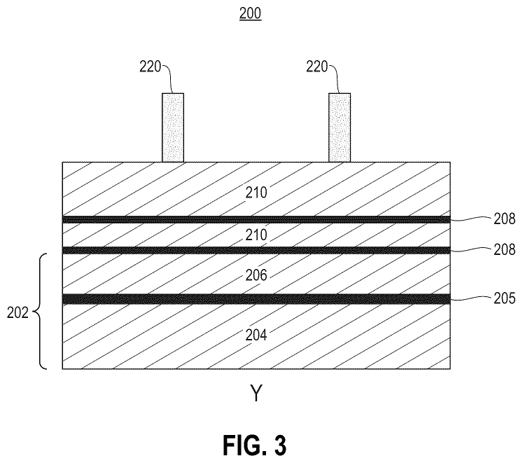

FIG. 2 depicts a partial top-down view of a semiconductor IC device 200 that includes or is to include transistors that have channel(s) that can have relatively different or variable effective channel widths, according to embodiments of the disclosure. As currently depicted, semiconductor IC device 200 include a pair of channels 209 and replacement gate structures 290. FIG. 2 also depicts various cross-sectional planes of the various cross-sectional views of FIG. 3 through FIG. 13. The X cross-sectional plane is between adjacent channels of the pair of channels 209 and across replacement gate structures 290. The Y1 cross-sectional plane is between adjacent replacement gate structures 290 and across the channels. The Y2 cross-sectional plane is through a replacement gate structure 290 and across the channels.

FIG. 3 depicts an initial fabrication cross-sectional view of semiconductor IC device 200 that includes or is to include transistors that have channel(s) that can have relatively different or variable effective channel widths, according to embodiments of the disclosure. At the present fabrication stage, alternating sacrificial layers 208 and channel layers 210 and channel mandrels 220 may be formed over a substrate structure 202.

The substrate structure 202 may include a semiconductor material including, but not limited to, silicon (Si), silicon germanium (SiGe), silicon carbide (SIC), Si:C (carbon doped silicon), silicon germanium carbide (SiGeC), carbon doped silicon germanium (SiGe:C), III-V, II-V compound semiconductor or other like semiconductor. In addition, multiple layers of the semiconductor materials can be used as the semiconductor material of the substrate structure 202. The substrate structure 202 can be a bulk substrate, or a semiconductor-on-insulator substrate such as, but not limited to, a silicon-on-insulator (SOI), silicon-germanium-on-insulator (SGOI) or III-V-on-insulator substrate including a buried insulating layer, such as, for example, a buried oxide or nitride layer. In the depicted implementation, the substrate structure 202 includes an upper substrate 206, a lower substrate 204, and an etch stop layer 205 between the upper substrate 206 and the lower substrate 204. The upper substrate 206 and the lower substrate 204 may be comprised of any suitable material(s) including those listed above, and the etch stop layer 205 may be a dielectric material with etch selectivity to one or both of the upper substrate 206 and/or the lower substrate 204. In an example, the lower substrate 204 may be composed of Si. The etch stop layer 205 may be composed of SiGe and may be epitaxially grown from the top surface of lower substrate 204 and the upper substrate 206 may be composed of Si and may be epitaxially grown from the top surface of etch stop layer 205.

The alternating sacrificial layers 208 and channel layers 210 may be formed by fabricating the alternating sacrificial layers 208, such as SiGe sacrificial layers, and channel layers 210, such as Si layers, upon the substrate structure 202. The alternating sacrificial layers 208 can have Ge percentages ranging from 20% to 45%. In an implementation, the alternating sacrificial layers 208 and channel layers 210 may be formed by epitaxially growing each layer until the desired number and desired thicknesses of the layers are achieved. Any number of alternating layers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the alternating sacrificial layers 208 can be formed from SiGe and that the channel layers 210 can be formed from Si, it should be understood that any appropriate materials can be used instead, as long as the semiconductor materials have etch selectivity with respect to one or more of the others, as is consistent with the description of the fabrication stages herein. Although it is specifically contemplated that the alternating layers may formed by epitaxial growth, such layers can be formed by any appropriate deposition mechanism.

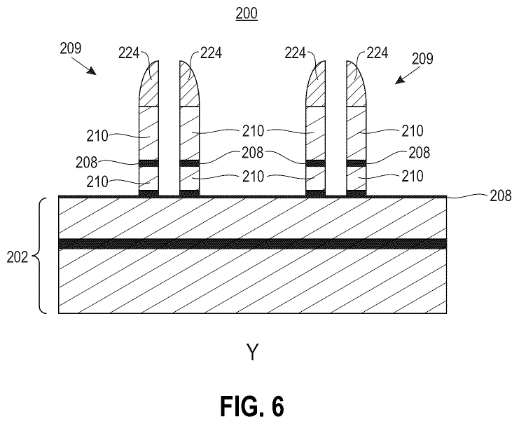

The one or more channel mandrels 220 may comprise, but are not necessarily limited to, amorphous silicon (a-Si), amorphous carbon, polycrystalline silicon, polycrystalline silicon germanium, amorphous silicon germanium, polycrystalline germanium, and/or amorphous germanium, are formed on the topmost layer of the channel layers 210 and spaced apart from each other. The channel mandrel 220 formation can be done by various patterning techniques, including, but not necessarily limited to, lithography patterning followed by directional etching and/or a sidewall image transfer (SIT) process, for example. In some embodiments, the process includes depositing a blanket of channel mandrel 220 material and using lithography followed by directional etching (e.g., RIE, or the like) to form the one or more channel mandrels 220. The channel mandrels 220 may have a dimension that may effectively define a distance between the pair of channels 209, as illustratively depicted in FIG. 6.

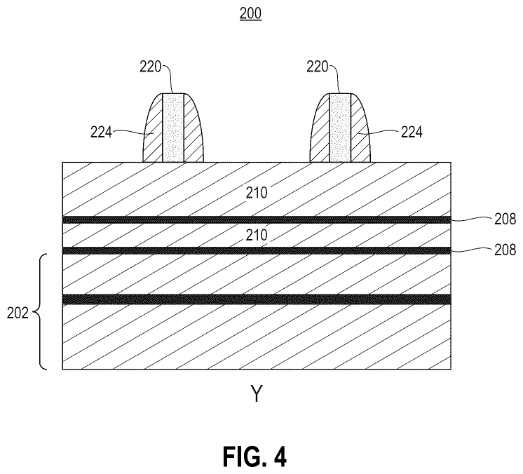

FIG. 4 depicts a fabrication cross-sectional view of semiconductor IC device 200 that includes or is to include transistors that have channel(s) that can have relatively different or variable effective channel widths, according to embodiments of the disclosure. At the present fabrication stage, sidewall image transfer (SIT) spacer(s) 224 may be formed upon the sidewall(s) of the channel mandrels 220.

The SIT spacer(s) 224 may be a conformal film and can be deposited and then followed by an etch back process (e.g., RIE, or the like). The deposition of material upon the mandrel 220 may also be referred to as spacer formation around vertical sides of each mandrel 220. The SIT spacer(s) 224 material can include, but is not limited, an oxide, such as silicon oxide (SiOₓ) (where x is, for example, 2 in the case of silicon dioxide (SiO₂), or 1.99 or 2.01), formed by low-pressure chemical vapor deposition (LPCVD), PECVD, sub-atmospheric chemical vapor deposition (SACVD), rapid thermal chemical vapor deposition (RTCVD), in-situ radical assisted deposition, high temperature oxide (HTO) deposition, low temperature oxide (LTO) deposition, ozone/TEOS deposition, limited reaction processing CVD (LRPCVD). Alternatively, some other dielectric materials, such as SiOCN, SiCN, SiOC, can be used as the material for SIT spacer(s) 224. A height of the mandrels 220 and corresponding SIT spacer(s) 224 can be in the range of, but is not necessarily limited to, 30 nm to 100 nm.

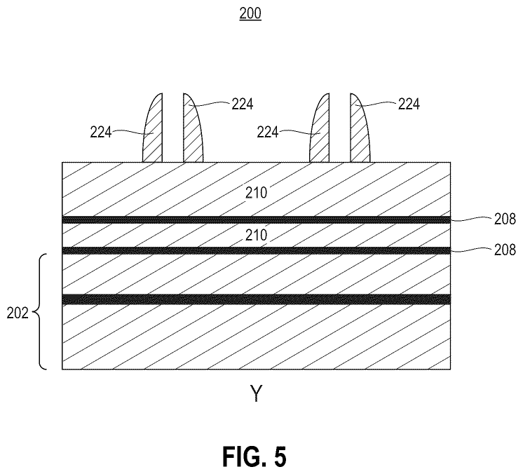

FIG. 5 depicts a fabrication cross-sectional view of semiconductor IC device 200 that includes or is to include transistors that have channel(s) that can have relatively different or variable effective channel widths, according to embodiments of the disclosure. At the present fabrication stage, the one or more mandrels 220 may be removed. The mandrel(s) 220 may be removed by a substrative removal technique such as an etch. The etch may be selective to the SIT spacer(s) 224 and the topmost layer of the channel layers 210.

FIG. 6 depicts a fabrication cross-sectional view of semiconductor IC device 200 that includes or is to include transistors that have channel(s) that can have relatively different or variable effective channel widths, according to embodiments of the disclosure. At the present fabrication stage, one or more pairs of channels 209 may be formed.

The channels 209 may be formed by patterning the channel layers 210. For example, selective portions of the channel layers 210 may be removed by an etch that is controlled to a certain depth (depending on design). In an example, the bottommost layer of the alternating sacrificial layers 208 may be utilized as an etch stop. The etch may transfer the pattern of the SIT spacer(s) 224 to the channel layers 210 to form the channels 209. For clarity, the present disclosure illustrates two pairs of channels 209. However, more or less channels 209 can be formed.

The formation of the channels 209 may effectively form in segments of the channel layers 210. These segments of the channel layers 210 may therefore be referred to herein as channel segments 210. Similarly, the formation of the channels 209 may effectively form in segments of the alternating sacrificial layers 208. These segments of the alternating sacrificial layers 208 may therefore be referred to herein as alternating sacrificial segments 208.

The channel segments 210 may be vertically stacked. For example, a top channel segments 210 is vertically stacked over a bottom channel segment 210 with an alternating sacrificial layer 208 therebetween. Further, each of the channel segments 210 may have a vertical orientation (i.e. vertical height is greater than horizontal thickness). In other words, each of the channel segments 210 may have a portrait orientation, as opposed to a landscape orientation, as depicted in the illustrated cross-section. In examples, respective sidewalls of the vertically stacked channel segments 210 and the alternating sacrificial layer 208 therebetween may be substantially coplanar and/or substantially vertical, as depicted.

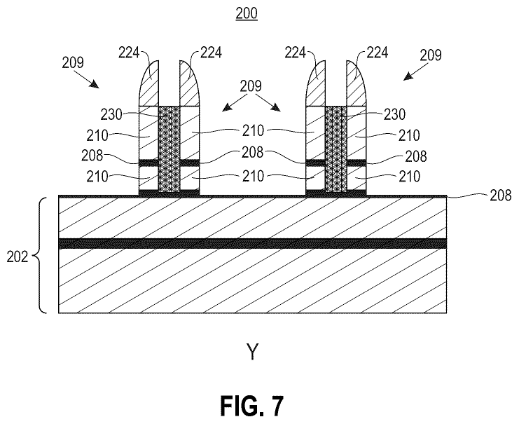

FIG. 7 depicts a fabrication cross-sectional view of semiconductor IC device 200 that includes or is to include transistors that have channel(s) that can have relatively different or variable effective channel widths, according to embodiments of the disclosure. At the present fabrication stage, a channel plug 230 may be formed between each channel of the pair of channels 209.

The channel plug(s) 230 may consist of a semiconductor material, such as SiGe. In an example, the channel plug(s) 230 may be deposited upon the bottommost layer of the alternating sacrificial layers 208 and between the pair of channels 209 by a blanket deposition and a subsequent etch back to remove undesired channel plug(s) 230 material. In another example, the channel plug(s) 230 may be epitaxially grown from the bottommost layer of the alternating sacrificial layers 208 and/or the surfaces of the pair of channels 209, followed by a etch back to remove undesired channel plug(s) 230 material.

In certain implementations, the channel plug(s) 230 may be formed or otherwise retained between and contacting respective sidewalls of the pair of channels 209 and upon and contacting a top surface of the bottommost layer of the alternating sacrificial layers 208. The top surface(s) of the channel plug(s) 230 may be substantially coplanar with or below one or more respective top surfaces of the pair of channels 209. In examples, a respective channel plug 230 structurally joins or otherwise associates the pair of channels 209 and may be referred herein as a channel row. In examples, the channel plug(s) 230 may serve as a etch mask so as to retain the portion of the substrate structure 202 thereunder in subsequent processing of the semiconductor IC device 200.

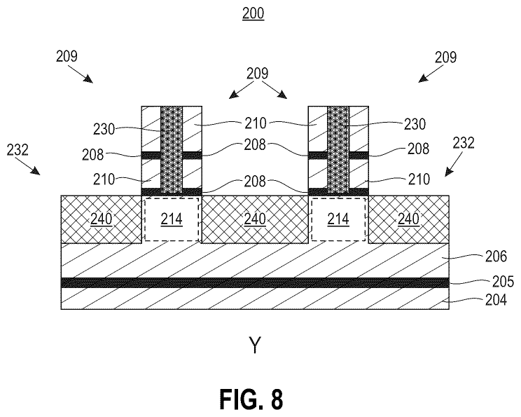

FIG. 8 depicts a fabrication cross-sectional view of semiconductor IC device 200 that includes or is to include transistors that have channel(s) that can have relatively different or variable effective channel widths, according to embodiments of the disclosure. At the present fabrication stage, substrate structure 202 may be partially recessed outside of the pair of channels 209 to form one or more shallow trench isolation (STI) region openings 232. Further, at the present fabrication stage, a STI region 240 may be formed within a respective STI region opening 232 and the SIT spacer(s) 224 may be removed.

The STI region openings 232 may be formed by a directional etching technique (e.g., RIE, or the like) that utilizes the SIT spacer(s) 224 and the channel plug(s) 230 as etch masks. The SIT spacer(s) 224 may protect the underlying pair of channels 209 and the channel plug(s) 230 may protect the underlying substrate structure 202 from the directional etch. Resultantly, a portion of the substrate structure 202 under the adjacent or pair of channels 209 and under the channel plug(s) 230 may be retained and may form a lower portion 214 of the pair of channels 209. For example, a portion of the upper substrate 206 under the pair of channels 209 and under the channel plug(s) 230 may be retained. A bottom or well surface of the STI region openings 232 may be above the etch stop layer 205.

The STI region(s) 240 may be formed by depositing a dielectric material including, but not necessarily limited to SiOₓ, LTO, HTO, flowable oxide (FOX), SiOC, SiOCN, or some other dielectric, into the STI region openings 232. The dielectric material can be deposited using deposition techniques including, but not necessarily limited to, CVD, plasma enhanced CVD, PECVD, RFCVD, PVD, ALD, MLD, MBD, PLD, LSMCD. As depicted, top surfaces of the STI region(s) 240 may be substantially coplanar with the respective bottom surfaces of the pair of channels 209 and/or the channel plug(s) 230. The STI region(s) 240 may directly contact the top surface of the recessed upper substrate 206 and respective sidewalls of the lower portion 214 of the pair of channels 209. In some examples, an STI region 240 may adequately electrically isolate a first cell that includes one or more transistors from a second cell that includes one of more transistors. The STI region 240 may also at least partially define or establish respective geometrical and/or structural boundaries of the cell(s).

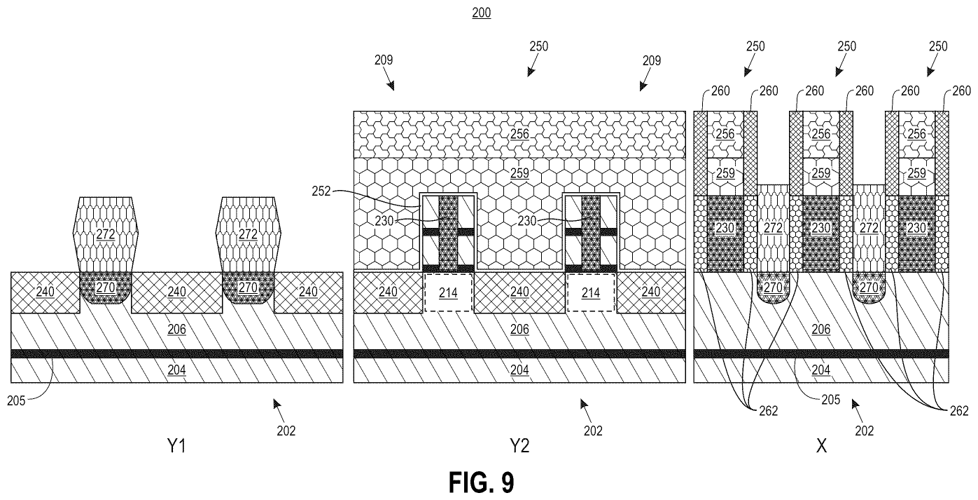

FIG. 9 depicts a fabrication cross-sectional view of semiconductor IC device 200 that includes or is to include transistors that have channel(s) that can have relatively different or variable effective channel widths, according to embodiments of the disclosure. At the present fabrication stage, sacrificial gate structures 250 may be formed, gate spacers 260 may be formed, gate inner spacers 262 may be formed, backside contact placeholders 270 may be formed, and source/drain (S/D) regions 272 may be formed.

The sacrificial gate structures 250 may include a sacrificial gate liner 252, a sacrificial gate 259, and a sacrificial gate cap 256. The sacrificial gate structures 250 may be formed by initially depositing a sacrificial gate liner layer (e.g., a dielectric, oxide, or the like) upon the one or more STI regions 240 and upon and around the one or more channel rows. The sacrificial gate structures 250 may further be formed by subsequently depositing a sacrificial gate layer (e.g., amorphous silicon, or the like) upon the sacrificial gate liner layer. The sacrificial gate structures 250 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 200.

The one or more sacrificial gate structures 250 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner 252, the sacrificial gate 254, and the sacrificial gate cap 256, respectively, of each of the one or more sacrificial gate structures 250.

The illustrated semiconductor IC device 200 may be further fabricated by forming gate spacers 260 around the sacrificial gate structures 250. The gate spacer(s) 260 may be formed by a conformal deposition of a dielectric material, such as silicon nitride, SiBCN, SiNC, SIN, SiCO, SiNOC, or a combination thereof, or the like, upon and around a respective sacrificial gate structure 250 and upon and around the one or more channel rows. Subsequently, undesired portions of dielectric material may be removed while desired portions the dielectric material may be retained and thereby form the gate spacer(s) 260 around the sacrificial gate structures 250.

The illustrated semiconductor IC device 100 may be further fabricated by forming recesses or openings within the one or more channel rows between gate spacers 260 of neighboring sacrificial gate structures 250. In other words, a single channel row may be separated, by one or more recesses, into multiple channel stacks each located underneath a portion of respective sacrificial gate structure 250 and associated gate spacers 260.

The channel row recess or opening may be formed to a depth to stop at the top surface of the STI regions 240. The undesired portions of channel rows may be removed by etching or other subtractive removal techniques. As the gate spacers 260 and the sacrificial gate structures 250 may be utilized to protect the underlying portions of channel rows, respective sidewalls of the pair of channels 209 and associated channel plug 230 may be substantially vertical and substantially coplanar with the outer sidewalls of the gate spacers 260 there above.

As used herein, “substantially vertical” sidewalls deviate from a direction normal to a major surface (e.g., top surface, etc.) of the substrate structure 202 by less than 5°, e.g., 0°, 1°, 2°, 3°, 4°, or 5°, including ranges between any of the foregoing values.

The illustrated semiconductor IC device 200 may be further fabricated by forming horizontal or lateral indents by laterally or horizontally removing respective portion(s) of the channel plug(s) 230 within the channel stacks. The indents may be formed by a reactive ion etch (RIE) process, which can remove portions of the channel plug(s) 230. The horizontal depth of the indents may be chosen to set a length for a replacement gate structure that is formed in place of one sacrificial gate structure 250. The directional RIE can use a boron-based chemistry or a chlorine-based chemistry, for example, which recesses or removes the exposed end portions of the channel plug(s) 230 (e.g., end portions of the channel plug(s) 230 directly below gate spacer 260). In alternative implementations, when the channel plug(s) 230 are not SiGe, the directional etch of the sacrificial the channel plug(s) 230 may generally be selective to the pair of channels 209, gate spacers 260, STI regions 240, and/or substrate structure 202.

The illustrated semiconductor IC device 200 may be further fabricated by forming a respective gate inner spacer 262 within each indent. The one or more gate inner spacer 262 can be formed by ALD or CVD or any other suitable deposition technique that deposits a dielectric material within the indent(s), thereby forming the gate inner spacer 262. In some examples, the gate inner spacer 262 are composed of a low-K dielectric material (a material with a lower dielectric constant relative to SiO₂), SIN, SiO, SiBCN, SiOCN, SiCO, etc. or any other suitable dielectric material. In certain implementations, after the formation of the gate inner spacer 262, a directional etch process is performed to create substantially vertical sidewalls of the gate inner spacer 262 that are coplanar with the substantially vertical sidewalls or end surfaces of pair of channels 209, of the gate spacers 260, or the like.

The illustrated semiconductor IC device 200 may be further fabricated by forming one or more backside contact placeholders 270 within the substrate structure 202 in between adjacent sacrificial gate structures 250 within a respective opening. In one example, a respective backside contact placeholder 270 may be formed in all opening location(s), such that a respective backside contact placeholder 270 is located underneath each S/D region 272.

If the recesses are not of sufficient depth, the one or more backside contact placeholders 270 may be formed by forming one or more backside contact placeholder openings within the substrate structure 202 generally in between adjacent sacrificial gate structures 250 and below the prior respective one or more openings. The one or more backside contact placeholders 270 may be further formed by epitaxially growing an epitaxial material from exposed substrate structure 202 surface(s) within the one or more backside contact placeholder(s) openings. In an example, the epitaxial material of the one or more backside contact placeholders 270 may be chosen to be etch selective to the material of the S/D region(s) 272, the material of the upper substrate 206, or the like.

In an example, as depicted, a barrier layer may be formed upon the backside contact placeholder 270 within the one or more backside contact placeholder(s) cavities. The barrier layer may be utilized to help protect or mask the associated backside contact placeholder 270 during the etching process(es). The barrier layer(s) may be epitaxially grown. For example, the one or more backside contact placeholders 270 may be SiGe and the barrier layer(s) may be Si.

The illustrated semiconductor IC device 200 may be further fabricated by forming one or more respective S/D regions 272 upon a respective backside contact placeholder 270 or barrier layer (if present). For example, p-doped S/D regions 272 may be formed in a first formation sequence and then n-doped S/D regions 272 may be formed in a second formation sequence, or vice versa.

Each S/D region 272 may form either a source or a drain, respectively, of a respective transistor and is connected to respective end surfaces of the pair of channels 209 within the nanolayer stack. Each S/D region 272 is composed of a semiconductor material and a dopant. As used herein, a “source/drain” region can be a source region or a drain region depending on subsequent wiring and application of voltages during operation of the applicable transistor.

The semiconductor material that provides each of the S/D regions 272 may be composed of one of the semiconductor materials mentioned above for the semiconductor structure 202. For example, the semiconductor material that provides the S/D region 272 can be compositionally the same, or compositionally different from each channel 209. The dopant that is present in the S/D regions 272 can be either a p-type dopant or an n-type dopant. The term “p-type” refers to the addition of impurities to an intrinsic semiconductor that creates deficiencies of valence electrons. “n-type” refers to the addition of impurities that contributes free electrons to an intrinsic semiconductor. When the semiconductor material is doped with a p-type dopant, the resulting S/D regions 272 are referred to herein as being p-doped and when the semiconductor material is doped with a n-type dopant, the resulting S/D regions 272 are referred to herein as being n-doped.

The S/D regions 272 may be epitaxially grown or formed. In some examples, the S/D regions 272 are formed by in-situ doped epitaxial growth. The use of an in-situ doping process is merely an example. For instance, one may instead employ an ex-situ process to introduce dopants into the S/D regions 272. Other doping techniques can be used to incorporate dopants in the S/D regions 272.

In some examples, the epitaxial growth that forms the S/D region 272 occurs or is promoted from the top surface of upper substrate 206, from the upper surface of backside contact placeholders 270 (or barrier layer thereupon), from the exposed surface(s) of the pair of channels 209, or the like, while epitaxial growth may be limited or does not occur from neighboring STI regions 240.

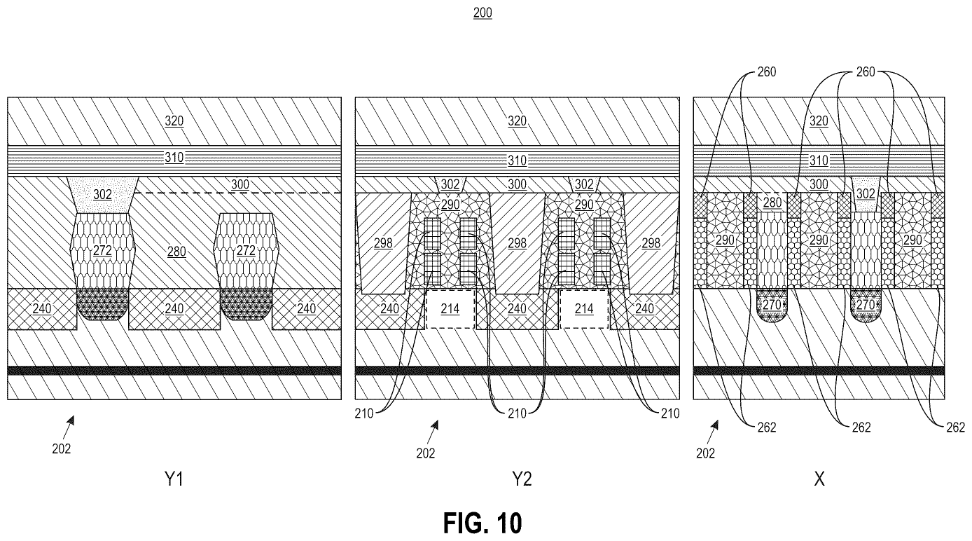

FIG. 10 depicts a fabrication cross-sectional view of semiconductor IC device 200 that includes or is to include transistors that have channel(s) that can have relatively different or variable effective channel widths, according to embodiments of the disclosure. At the present fabrication stage, ILD 280 may be formed, sacrificial gate structures 250 may be removed, replacement gate structures 290 may be formed in place of the removed sacrificial gate structures 250, gate cut regions 298 may be formed, ILD 300 may be formed, frontside contacts 302 may be formed, a frontside BEOL network 310 may be formed, and a carrier wafer 320 may be bonded to the semiconductor IC device 200.

ILD 280 may be formed on the one or more S/D regions 272, upon the top surface of STI regions 240, upon the gate spacers 260, or the like. ILD 280 may be formed by depositing a dielectric material, such as silicon oxide, silicon nitride, SiBCN, SiNC, SIN, SiCO, SiNOC, or a combination thereof, or the like, as a blanket layer. In an embodiment, ILD 280 may be formed to a thickness above the top surface of semiconductor device 200 and subsequently planarized by a chemical mechanical polish (CMP) or etch, such that the top surface of sacrificial gate structure 250 is exposed (e.g., sacrificial gate cap 256 is removed by the CMP) and is coplanar with a top surface of the sacrificial ILD 280 and with a top surface of gate spacers 260.

Upon exposing a portion of the sacrificial gate structure 250, the remaining sacrificial gate structure 250 may be removed by an etch. The removal of sacrificial gate structure 250 may expose the channel segments 210 and alternating sacrificial layers 208 of the pair of channels 209 between gate spacers 260, and/or the like. Next, or simultaneously, the channel segments 210 may be released by removing the sacrificial layer segments 208 within the nanolayer stacks. The alternating sacrificial layers 208 may be removed by a removal technique, such as one or more series of etches. After the removal of alternating sacrificial layers 208, void spaces may be formed above and/or below the channel segments 210. For example, the top channel segment 210 may be separated from the bottom channel segment 210. Similarly, the bottom channel segment 210 may be separated from the lower portion 214 of the pair of channels 209.

A replacement gate structure 290 may then formed in place of the removed sacrificial gate structure 250 in between gate spacers 260 and upon and around the respective channel segments 210 of the pair of channels 209. The replacement gate structure 290 can include the gate dielectric (not shown) and replacement gate material(s). The gate dielectric can be the gate dielectric associated with the replacement gate structure 250 or if removed, a subsequent gate dielectric that can comprise any suitable dielectric material, including but not limited to silicon oxide, silicon nitride, silicon oxynitride, high-k materials, or any combination of these materials. The gate dielectric can be formed by any suitable deposition process or the like. In some embodiments, the gate dielectric has a thickness ranging from 1 nm to 5 nm, although less thickness and greater thickness are also conceived.

The replacement gate structure 290 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAIC), tungsten silicide (WSi), tungsten nitride (WN), ruthenium oxide (RuO2), cobalt silicide (CoSi), nickel silicide (NiSi)), transition metal aluminides (e.g. Ti₃Al, ZrAl), TaC, TaMgC, carbon nanotube, conductive carbon, graphene, or any suitable combination of these materials.

In some embodiments, the replacement gate structure 290 may further comprise a workfunction layer (not shown). The workfunction layer can be a workfunction metal (WFM). The WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

The replacement gate structure 290 may be formed by initially forming the gate dielectric layer between gate spacers 260 around the channel segments 210 of the pair of channels 209 and upon the top surface of STI regions 240. The replacement gate structure 190 may further be formed by subsequently forming a gate conductor layer upon the gate dielectric layer. The gate conductor layer and gate dielectric layer may be patterned using lithography and etch process to remove undesired portions and retain desired portion(s), respectively. The retained desired portion(s) of the gate conductor layer and gate dielectric layer may form the replacement gate structure 290. A CMP, etch process, or another subtractive removal technique, may remove undesired portions of replacement gate structure 290, such that a top surface of replacement gate structure 290 is coplanar with the top surface of gate spacer 260, ILD 280, or the like. In some implementations, the replacement gate structure 290 can be recessed below the top surface of semiconductor device 200 and a dielectric gate cap (not shown) can be formed upon the recessed replacement gate structure 290. For clarity, to achieve expected FinFET functionality, the replacement gate structure 290 may control charge carrier flow between the channel segments 210 of the pair of channels 209 between the associated S/D regions 272. For clarity, the replacement gate structure 290 may contact an entire perimeter of the channel segments 210 of the pair of channels 209, as depicted in the Y2 cross-section.

The gate cut region 298 may be formed by forming and patterning a gate cut mask and utilizing such to forming gate cut region openings within or across the replacement gate structures 290. The gate cut region openings may have a well or bottom surface within an underlying STI region 240. The pattern transfer etching process to form the gate cut opening may be an anisotropic etch. In certain embodiments, a dry etching process such as, for example, RIE can be used. In other embodiments, a wet chemical etchant can be used. In still further embodiments, a combination of dry etching and wet etching can be used. The gate cut region 298 may be formed by depositing a gate cut dielectric material, such as, for example, porous silicates, carbon doped oxides, silicon dioxides, silicon nitrides, silicon oxynitrides, or other dielectric materials, within the gate cut region openings. Any appropriate deposition technique for forming the gate cut dielectric layer can be utilized. The gate cut dielectric layer can be formed using, for example, CVD, PECVD, ALD, flowable CVD, spin-on dielectrics, or PVD.

For clarity, the gate cut region 298 may divides and/or electrically separates one or more replacement gate structures 290 into a first gate or gate structure and a second gate or gate structure. The first gate or gate structure may be associated with the first transistor and the second gate or gate structure may be associated with the second transistor. Subsequently, the semiconductor IC device 200 may be planarized by a CMP, or the like. Therefore, respective top surfaces of the ILD 280, replacement gate structures 290, gate spacers 260, and gate cut regions 298 may be substantially horizontal and/or substantially coplanar.

The illustrated semiconductor IC device 200 may be further fabricated by forming ILD 300 upon the ILD 280, upon the replacement gate structures 290, and upon the gate spacers 260. The ILD 300 may be formed by depositing a dielectric material, such as silicon oxide, silicon nitride, SiBCN, SINC, SIN, SiCO, SiNOC, or a combination thereof, or the like, as a blanket layer. In an embodiment, ILD 300 may be planarized by a CMP or etch, above the top surface of replacement gate structures 290.

The illustrated semiconductor IC device 200 may be further fabricated by forming frontside contacts 302 within the ILD 300 and/or the ILD 280. The frontside contacts 302 may be formed by patterning respective frontside contact openings within the ILD layer(s), respectively, from the frontside (i.e., from above the semiconductor IC device 200, as depicted, downward to respective structures thereof). The frontside contacts 302 may be in direct or indirect physical and electrical contact with respective material(s) of one or more regions of the semiconductor IC device 200.

The frontside contact(s) 302 may be formed by depositing conductive material such as metal into the respective frontside contact opening(s). In an example, frontside contact(s) 302 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 302 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 200. First, a frontside BEOL network 310 is formed on the frontside of the semiconductor device 200. Subsequently, a backside BEOL network may be formed.

In the depicted example, the frontside BEOL network 310 is formed over the ILD 300 and upon the frontside contacts 302. Respective wires within the frontside BEOL network 310 may be electrically connected to the one or more S/D regions 272, to the one or more replacement gate structure(s) 290, or the like, by a respective frontside contact(s) 302. For example, respective wire(s) within the frontside BEOL network 310 may be electrically connected to appropriate S/D regions 272 by a frontside contact 302, and another different group of respective wire(s) within the frontside BEOL network 310 may be electrically connected to appropriate replacement gate structures 290, etc.

The frontside BEOL network 310 can include one or more interconnect dielectric material layers (including one of the dielectric materials mentioned above for the frontside ILD 176) and contains conductive wires (the conductive wires can be composed of any electrically conductive metal or electrically conductive metal alloy) embedded therein. In some embodiments, the frontside conductive wires within the frontside BEOL network 310 are composed of Cu. The frontside BEOL network 310 can include “x” numbers of frontside metal levels, wherein “x” is an integer starting from 1. The frontside BEOL network 310 may further contain conductive pads that are connected to one or more of the conductive wires and may be used to connect the semiconductor IC device 200 to an external and/or higher-level structure, such as a chip carrier, motherboard, or the like.

The illustrated semiconductor IC device 200 may be further fabricated by bonding carrier wafer 320 to the frontside BEOL network 310. The carrier wafer 320 can include one of the semiconductor materials mentioned above for the semiconductor structure and the carrier wafer 320 may be attached to the semiconductor IC device 200 by a wafer-to-wafer bonding technique.

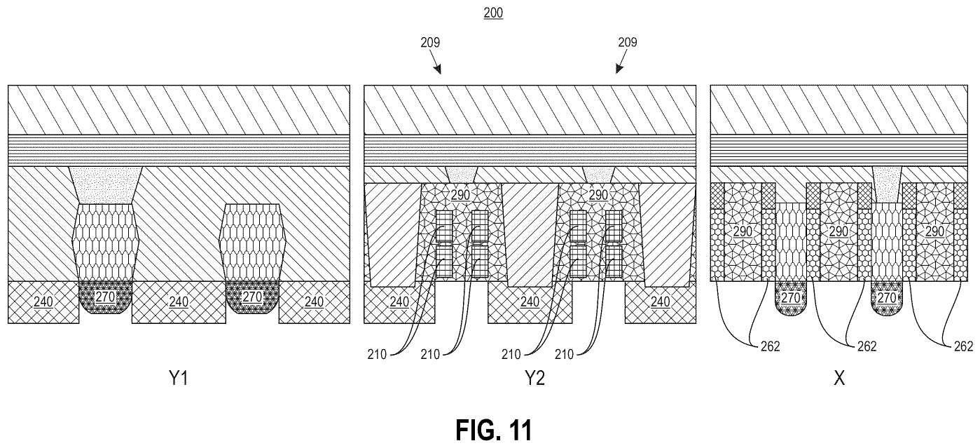

FIG. 11 depicts a fabrication cross-sectional view of semiconductor IC device 200 that includes or is to include transistors that have channel(s) that can have relatively different or variable effective channel widths, according to embodiments of the disclosure. At the present fabrication stage, the substrate structure 202 may be removed.

The substrate structure 202 may be removed by flipping the semiconductor IC device 200 (not shown) and removing the lower substrate 204 using any removal technique, such as a combination of wafer grinding, CMP, dry, and/or wet etch. In the example depicted, lower substrate 204 is removed by an etch that utilizes etch stop layer 205 as the etch stop. In this example, removal of lower substrate 204 exposes the bottom surface of etch stop layer 205.

The substrate structure 202 may be further removed by removing the etch stop layer 205 and the upper substrate 206. The etch stop layer 205 may be removed by a subtractive removal technique such as a CMP, dry and/or wet etch. Upon removal of the etch stop layer 205, the bottom surface upper substrate 206 is exposed. The removal of etch stop layer 205 may be selective to the material of upper substrate 206. For example, etch stop layer 205 is removed by an etch that utilizes upper substrate 206 as the etch stop.

The upper substrate 206 may be removed by an appropriate substrative removal technique, such as an etch. The etch may be timed or otherwise controlled to remove the material of substrate 206 selective to the STI regions 240, to the backside contact placeholders 270, to the replacement gate structures 290, and/or to the gate inner spacers 262, or the like. In an example, the etch that removes the upper substrate 206 may be controlled to result in the respective bottom surface portion(s) of replacement gate structures 290 to be exposed. For example, the etch removes the lower portion 214 of the pair of channels 209 and exposes a portion of the bottom surface of the replacement gate structure 290. For clarity, as depicted and at the present stage of fabrication, each of the channels 209 may have the same number and general channel segment 210 geometry. For example, a first channel and a second channel may both have the same number and orientation of channel segments 210.

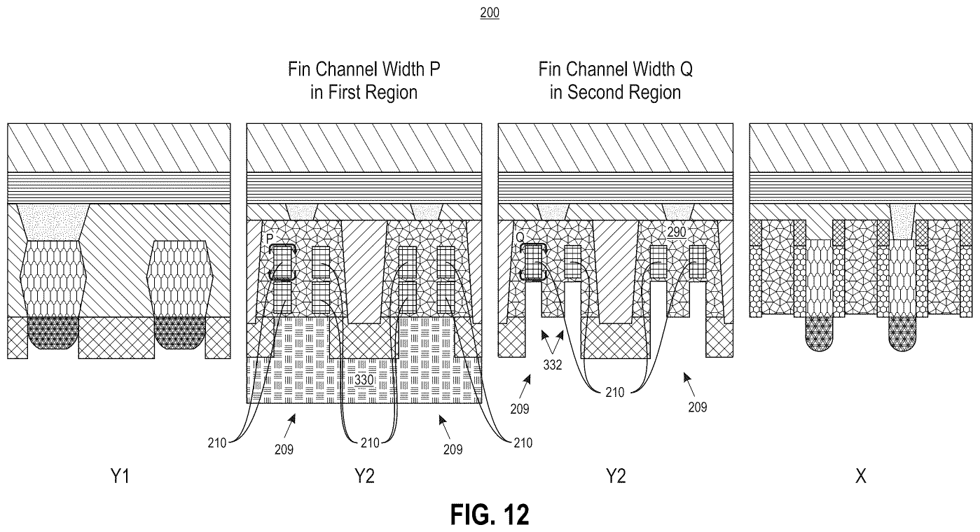

FIG. 12 depicts a fabrication cross-sectional view of semiconductor IC device 200 that includes transistors that have channels (i.e., pair of channels 209) that can have relatively different or variable effective channel widths, according to embodiments of the disclosure. At the present fabrication stage, some of the pair of channels 209 within a second region may (e.g., a first Y2 region) be further recessed from the backside while some of the pair of channels 209 within a first region (e.g., a second Y2 region) may be protected.

The first region may be protected by depositing a mask 330, such as a dielectric, OPL, or the like. The mask may be patterned and opened in the second Y2 cross sectional plane region to expose the second Y2 cross sectional plane region.

In an example, an etch that further removes the pair of channels 209 in the exposed second region may cause such pair of channels 209 to be recessed above the bottom surface of their associated replacement gate structures 290. The etch may be controlled, timed, or the like, to achieve the desired channel 209 material removal. For example, the etch may remove the bottom channel segment 210 from the pair of channels 209. After punching through the replacement gate structures 290 to expose the bottom channel segment 210, the etch may utilize the replacement gate structures 290 as an etch stop. As such, the degree of channel 209 removal may be more controlled or improved relative to other techniques.

Consequently, the first region and the second region include one or more transistors with pair of channels 209 that have relatively different or variable effective channel widths P, Q. For example, the first region has a transistor with four channel segments 210, each substantially having a perimeter of P/4, to achieve an effective channel width of P. Similarly, the second region has a transistor with two channel segments 210, each substantially having the same dimension perimeter of P/4, to achieve an effective channel width of Q, where Q is less than P. For clarity, the effective channel width of each channel segment 210 may be two times a vertical channel height plus two times the horizontal channel thickness.

The semiconductor IC device 200 provides flexibility in achieving variable or different effective channel widths P, Q in different areas or regions of the semiconductor IC device 200. Subsequently, the mask 330 may be removed by a substrative removal technique, such as an etch, OPL ash, or the like.

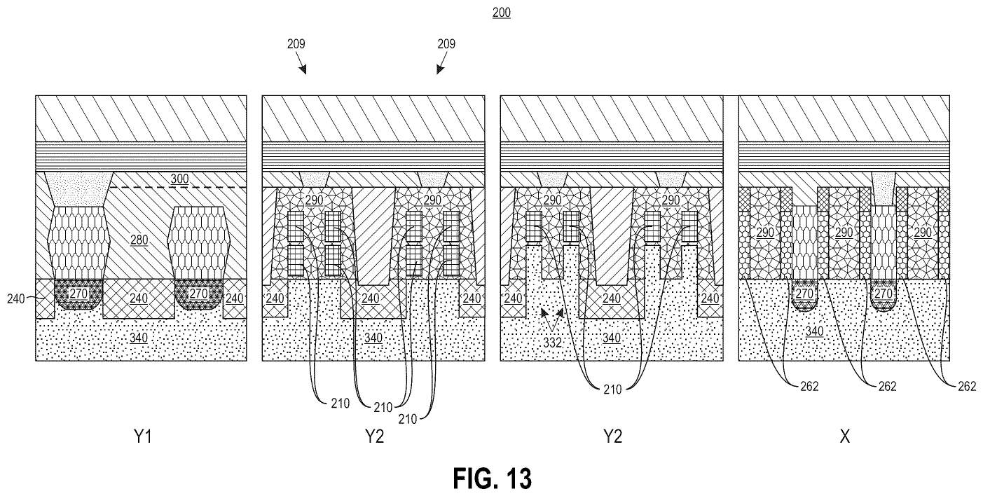

FIG. 13 depicts a fabrication cross-sectional view of semiconductor IC device 200 that includes transistors that have channels that have relatively different or variable effective channel widths, according to embodiments of the disclosure. At the present fabrication stage, a backside ILD 340 may be formed upon the backside of the semiconductor IC device 200.

The backside ILD 340 may be formed upon the backside contact placeholder(s) 270, upon the STI regions 240, upon the backside of the replacement gate structures 290, upon the backside of the inner gate spacers 262, and/or the like. The backside ILD 340 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 340 can be utilized. The backside ILD 340 can be formed using, for example, CVD, PECVD, ALD, flowable CVD, spin-on dielectrics, or PVD.

In an example, the material of the backside ILD 340 may be the same material as the ILD 280 and/or as the ILD 300. In alternative examples, the material(s) may be different. For example, the material of the backside ILD 340 may be chosen to achieve a predetermined electrical isolation metric that the dielectric material of the ILD 280 and/or the ILD 300 could not achieve, if utilized. For example, frontside ILD 280 and/or the ILD 300 may be silicon dioxide and the backside ILD 340 may be a low-K dielectric material.

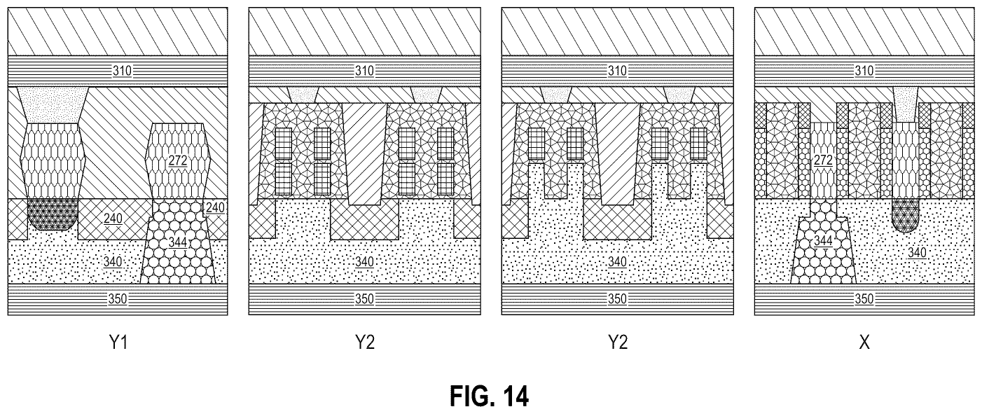

FIG. 14 depicts a fabrication cross-sectional view of semiconductor IC device 200 that includes transistors that have channels that have relatively different or variable effective channel widths, according to embodiments of the disclosure. At the present fabrication stage, backside contact(s) 344 may be formed and a backside BEOL network 350 may be formed.

Backside contacts 344 may be formed by forming an associated backside contact opening within the backside ILD 340. The backside contact opening(s) may be formed by the same or shared lithography and etch process(es), or sequential lithography and etch processes. In such process(es), a mask (not shown) may be applied to the backside of the semiconductor IC device 200 and patterned. Openings in the patterned mask may sequentially expose the portion(s) of the underlying material(s) that are to be removed while other protected portions of semiconductor IC device 200 may be protected and retained.

The backside contact opening(s) may be formed to expose the associated backside contact placeholder 270 there above (e.g., the backside contact placeholder 270 that is below a S/D region 272 that is not connected to the frontside BEOL network 310). The backside contact placeholder(s) 270 that are exposed by respective backside contact opening(s) may be removed by a substrative removal technique, such as an etch, and are therefore not depicted.

Alternatively, the exposed S/D region(s) 272 may be exposed and at least partially gouged, or in other words, a lower portion of the exposed S/D region 272 is removed while an upper portion of the exposed S/D region(s) 272 is retained. The lower portion of the S/D region(s) 272 may be removed by a subtractive removal technique, such as an etch.

Respective backside contact(s) 344 may be formed within a respective backside contact opening against the associated S/D region 272 by depositing conductive material, such as metal, therein. In an example, backside contact(s) 344 may be simultaneously formed by depositing a liner, such as Ni, NiPt or Ti, etc. onto the backside of semiconductor IC device 200 and into the backside contact openings, depositing an adhesion liner, such as TiN, TaN, etc. upon the liner, and by depositing a conductive fill, such as Al, Ru, W, Co, Cu, etc. upon the adhesion liner. Subsequently, a planarization process, such as a CMP, may expose a bottom surface of the backside ILD 340. As a result, the respective bottom surfaces of backside contact(s) 344 and backside ILD 340 may be substantially horizontal and/or substantially coplanar.

The backside BEOL network 350, such as a backside power distribution network (BSPDN) may be formed upon the backside contact(s) 344 and upon the backside ILD 340. The backside BEOL network 350 may include signal wires for signal routing and power wires for providing power potential (e.g., VDD, VSS, etc.). The backside BEOL network 350 may allow for the distribution of power wires and signal wires between both the frontside and backside of the semiconductor IC device. The backside BEOL network 350 may further allow for the full or partial decoupling of signal routing and/or power routing and/or allows for dividing or splitting power wires and/or signal wires between both the frontside and backside of the semiconductor IC device 200. By incorporating the backside BEOL network 350, routing congestion may be reduced, which may lead to further semiconductor IC device 200 scaling. For example, semiconductor IC devices 200 that incorporate a backside BEOL network can result in a 30% area reduction and improved current-resistance (IR) drop compared to typical semiconductor IC devices that include solely a frontside BEOL network.

The backside BEOL network 350 may be electrically connected to the one or more S/D regions 272 by way of a particular backside contact 344. For example, a first backside wire within the backside BEOL network 350 may be electrically connected the backside contact 344, or the like. The backside BEOL network 350 can include one or more interconnect dielectric material layers and contains backside conductive wires and/or interconnects, such as VIAs, embedded therein. In some embodiments, the backside wires within the backside BEOL network 350 are composed of Cu. The backside BEOL network 350 can include “x” numbers of backside metal levels, wherein “x” is an integer starting from 1. If not included in frontside BEOL network 310, backside BEOL network 350 may further contain conductive pads that are connected to one or more of the backside metal wires and may be used to connect the semiconductor IC device 200 to the external and/or higher-level structure.

In an example, signal routing and power routing is effectively split between the frontside BEOL network 310, depicted for example in FIG. 10, and the backside BEOL network 350. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 200 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

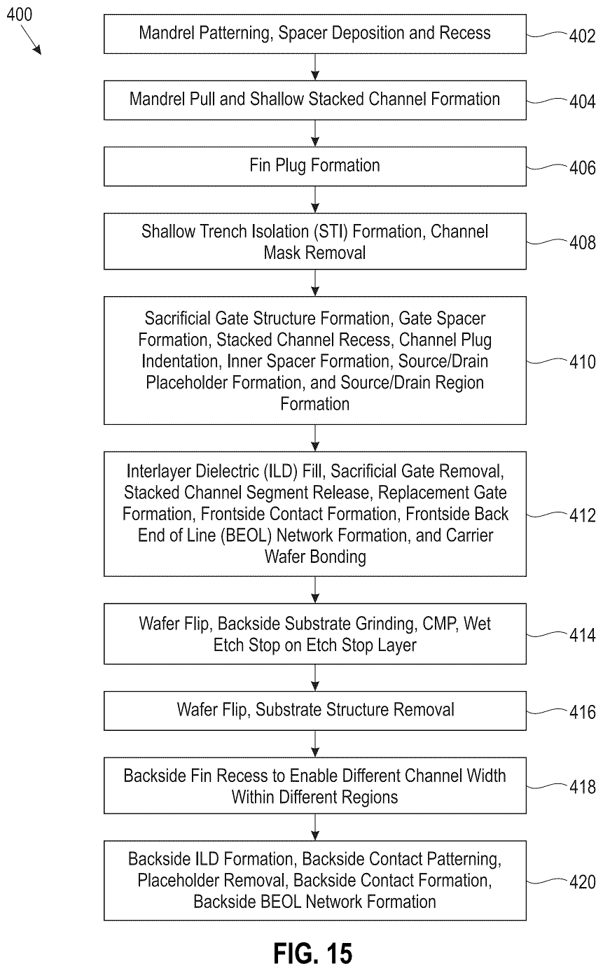

FIG. 15 depicts a method 400 of fabricating semiconductor device that that includes channels that have relatively different or variable effective channel widths, according to embodiments of the disclosure. Method 400 begins at block 402 by forming one or more channel mandrels 220 and one or more SIT spacers 224 over underlying structures, such as alternating channel layers 210 and alternating sacrificial layers 208 that may be formed upon a substrate structure 202. Method 400 may continue, at block 404, with a channel mandrel 220 pull and stacked channel formation. For example, the channel mandrels 220 are removed and the vertically stacked channel segments 210 within the pair of channels 209 are formed under the SIT spacers 224 by a recess.

Method 400 may continue, at block 406, with channel plug 230 formation. For example, fin plugs 230 are formed and structurally tie together the pair of channels 209. The channel plug 230 and the SIT spacers 224 may protect the underlying regions during further processing.

Method 400 may continue, at block 408, with forming STI regions 240 and removing the fin mask (i.e., SIT spacers 224). Method 400 may continue, at block 410, with forming sacrificial gate structures 250, with forming gate spacers 260, with recessing the channel row (i.e., pair of channels 209 and channel plug 230 therebetween) between adjacent sacrificial gate structures 250, with horizontally indenting the channel plug 230, with forming an inner gate spacer 262 within the horizontal indent, with forming a backside contact placeholder 270, and with forming S/D regions 272.

Method 400 may continue, at block 412, with forming ILD 280, with sacrificial gate structure 250 removal, with channel segment 210 release, with replacement gate structure 290 formation, with gate cut region 298 formation, with ILD 300 formation, with frontside contact 302 formation, with frontside BEOL network 310 formation, and with attaching carrier wafer 320.

Method 400 may continue, at block 414 and at block 416, with flipping the carrier wafer and with backside substrate structure 202 removal (e.g., substrate grinding, CMP(s), wet etch(es), or the like) that stops at the bottom surface of the upper portion(s) 212 of pair of channels 209. For example, the lower substrate 204 and the etch stop layer 205 can be sequentially removed. Next, the upper substrate 206 may be partially removed stopping at the bottom surface of the upper portion(s) 212 of pair of channels 209.

Method 400 may continue, at block 418, with selectively removing some of the bottom channel segment(s) 210 to enable different effective channel widths within different regions of the semiconductor IC device. For example, after the removal of some of the bottom channel segments 210 of the pair of channels 209, the semiconductor IC device includes a first region with a first channel that has a first effective channel width and a second region having a channel that has a second effective channel width that is less than the first effective channel width.

Method 400 may continue, at block 420, with backside ILD 340 formation, with backside contact patterning to expose a backside contact placeholder 270, with backside contact placeholder 370 removal, with backside contact 344 formation, and with backside BEOL network 350 formation.

The descriptions of the various embodiments of the disclosure have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first region comprising a first channel above a backside interlayer dielectric (ILD), the first channel includes a top channel segment that has a vertical orientation and is stacked over a bottom channel segment that also has a vertical orientation, wherein the first channel has a first effective channel width; and
a second region comprising a second channel that has a vertical orientation and is above the backside ILD, wherein the second channel has a second effective channel width that is less than the first effective channel width.

2. The semiconductor IC device of claim 1, wherein a top surface of the top channel segment is coplanar with a top surface of the second channel.

3. The semiconductor IC device of claim 2, wherein the first region further comprises a first transistor comprising first source/drain (S/D) regions and the first channel, wherein respective end surfaces of the top channel segment and the bottom channel segment are in direct contact with the first S/D regions.

4. The semiconductor IC device of claim 3, wherein the second region further comprises a second transistor comprising second S/D regions and the second channel, wherein respective end surfaces of the second channel are in direct contact with the second S/D regions.

5. The semiconductor IC device of claim 4, wherein a bottom surface of the bottom channel segment is above a top surface of first shallow trench isolation (STI) regions that at least partially bound the first transistor.

6. The semiconductor IC device of claim 5, wherein a bottom surface of the second channel is above the bottom surface of the bottom channel segment.

7. The semiconductor IC device of claim 6, wherein the first region further comprises a first gate structure that wraps around a perimeter of the top channel segment and a perimeter of the bottom channel segment.

8. The semiconductor IC device of claim 7, wherein the second region further comprises a second gate structure that wraps around a perimeter of the second channel.

9. The semiconductor IC device of claim 8, wherein a bottom surface of the second gate structure is substantially coplanar with a bottom surface of the first gate structure.

10. The semiconductor IC device of claim 9, wherein the backside ILD comprises a backside ILD portion between a bottom surface of the second channel and a top surface of second STI regions that at least partially bound the second transistor.

11. The semiconductor IC device of claim 10, further comprising:
a frontside back end of line (BEOL) network; and
a backside BEOL network.

12. The semiconductor IC device of claim 11, wherein the first gate structure and the second gate structure are respectively electrically connected to the frontside BEOL network.

13. The semiconductor IC device of claim 12, wherein one of the first S/D regions is electrically connected to the frontside BEOL network by a frontside contact and another of the first S/D regions is electrically connected to the backside BEOL network by a backside contact.

14. The semiconductor IC device of claim 13, wherein the first transistor further comprises a first gate inner spacer in contact with a sidewall of the first gate structure and with a sidewall of one of the first S/D regions and a second gate inner spacer in contact with an opposite sidewall of the first gate structure and with a sidewall of another of the first S/D regions.

15. A semiconductor integrated circuit (IC) device comprising:
a first transistor comprising a pair of segmented channels above a backside interlayer dielectric (ILD), the pair of segmented channels having a first effective channel width, wherein each segmented channel of the pair of segmented channels comprises a top channel segment that has a vertical orientation stacked over a bottom channel segment that also has a vertical orientation; and
a second transistor comprising a pair of second channels above the backside ILD, the pair of second channels having a second effective channel width that is less than the first effective channel width.

16. The semiconductor IC device of claim 15, wherein each second channel has a vertical orientation.

17. The semiconductor IC device of claim 16, wherein the first transistor further comprises first source/drain (S/D) regions and wherein respective end surfaces of the top channel segments and the bottom channel segments are in direct contact with the first S/D regions.

18. The semiconductor IC device of claim 17, wherein the first transistor further comprises a first gate structure that wraps around a respective perimeter of the top channel segments and a respective perimeter of the bottom channel segments.

19. The semiconductor IC device of claim 15, wherein respective top surfaces of the top channel segments are substantially coplanar with respective top surfaces of the pair of second channels.

20. A semiconductor integrated circuit (IC) device fabrication method comprising:
forming a first segmented channel and a second segmented channel within a substrate structure, wherein the first segmented channel and the second segmented channel both comprise a top channel segment that has a vertical orientation stacked over a bottom channel segment that also has a vertical orientation; and
from a backside of the semiconductor IC device, removing the bottom channel segment of the second segmented channel and maintaining the bottom channel segment of the first segmented channel.
